(19) United States
(12) Patent Application Publication
(10) Pub. No.: US 2016/0111151 A1
(43) Pub. Date: Apr. 21, 2016

(54) RESISTANCE VARIABLE MEMORY APPARATUS, READ/WRITE CIRCUIT UNIT AND OPERATION METHOD THEREOF

(71) Applicant: SK hynix Inc., Icheon-si (KR)

(72) Inventor: Jung Hyuk YOON, Icheon-si (KR)

(21) Appl. No.: 14/571,503

(22) Filed: Dec. 16, 2014

(30) Foreign Application Priority Data
Oct. 16, 2014 (KR) 10-2014-0139835

(51) Int. Cl. G11C 13/00

(52) U.S. Cl. CPC G11C 13/004; G11C 13/0064; G11C 13/0069; G11C 2013/0054

(57) ABSTRACT

A resistance variable memory apparatus may include a memory cell array. The resistance variable memory apparatus may include a read/write circuit unit. The read/write circuit unit may be configured for being controlled so that a reference value for the last verification operation has a different level from reference values for verification operations excluding the last verification operation, while a preset number of program and verification (PNV) cycles are performed in response to a write command for the memory cell array.

### CROSS-REFERENCES TO RELATED APPLICATION

The present application claims priority under 35 U.S.C. §119(a) to Korean application number 10-2014-0139835, filed on Oct. 16, 2014, in the Korean Intellectual Property Office, which is incorporated herein by reference in its entirety.

### BACKGROUND

1. Technical Field

Various embodiments generally relate to a semiconductor apparatus, and more particularly, to a resistance variable memory apparatus, a read/write circuit unit, and an operating method thereof.

2. Related Art

In a resistance variable memory device such as a phase change RAM (PRAM) or a resistance RAM (ReRAM), an information storage state is defined according to the resistance state of a data storage material. The resistance variable memory device may apply a program current during a program operation. The program current has a resistance state required by the data storage material.

A program and verification (PNV) method is an example of a program method for increasing the precision of a program operation. In the PNV method, a process of applying a program pulse to a memory cell to be programmed and a process of reading and verifying data of the memory cell are repeated a designated number of times.

When the data of the memory cell is verified, the cell data read from the memory cell may be compared to a reference value. Thus, in order to accurately determine the logic level of the cell data, setting the reference value is an important issue.

### SUMMARY

In an embodiment, a resistance variable memory apparatus may include a memory cell array, and a read/write circuit unit. The read/write circuit unit may be configured for being controlled so that a reference value for the last verification operation has a different level from reference values for verification operations excluding the last verification operation, while a preset number of program and verification (PNV) cycles are performed in response to a write command for the memory cell array.

In an embodiment, a read/write circuit unit may include a write circuit unit configured to program input data to a selected memory cell in response to a write command. The read/write circuit unit may include a read circuit unit. The read circuit unit may be configured to be controlled so that a reference value for the last verification operation has a different level from reference values for verification operations excluding the last verification operation, while a preset number of PNV cycles are performed in response to the write command.

In an embodiment, there is provided an operating method of a resistance variable memory apparatus including a read/write circuit unit. The operating method may include controlling the read/write circuit unit so that a reference value for the last verification operation has a different level from reference values for verification operations excluding the last verification operation, while a preset number of PNV cycles are performed in response to a write command.

### BRIEF DESCRIPTION OF THE DRAWINGS

FIG. 1 is a configuration diagram of a representation of a resistance variable memory device according to an embodiment.

FIG. 2 is a configuration diagram of a representation of a read/write circuit unit according to an embodiment.

FIG. 3 is a configuration diagram of a representation of a read circuit unit according to an embodiment.

FIG. 4 is a configuration diagram of a representation of reference value provider according to an embodiment.

FIG. 5 is a configuration diagram of a representation of a control signal generator according to an embodiment.

FIG. 6 is a configuration diagram of a representation of a read circuit unit according to an embodiment.

FIG. 7 is a configuration diagram of a representation of a reference provider according to an embodiment.

FIGS. 8 and 9 are conceptual views for explaining a representation of an operating method of the resistance variable memory apparatus according to an embodiment.

FIG. 10 illustrates a block diagram of an example of a representation of a system employing the resistance variable memory apparatus and/or read/write circuit unit and/or operating method in accordance with the embodiments discussed above with relation to FIGS. 1-9.

### DETAILED DESCRIPTION

Hereinafter, a resistance variable memory apparatus, a read/write circuit unit, and an operating method thereof according to the present disclosure will be described below with reference to the accompanying drawings through various examples of embodiments.

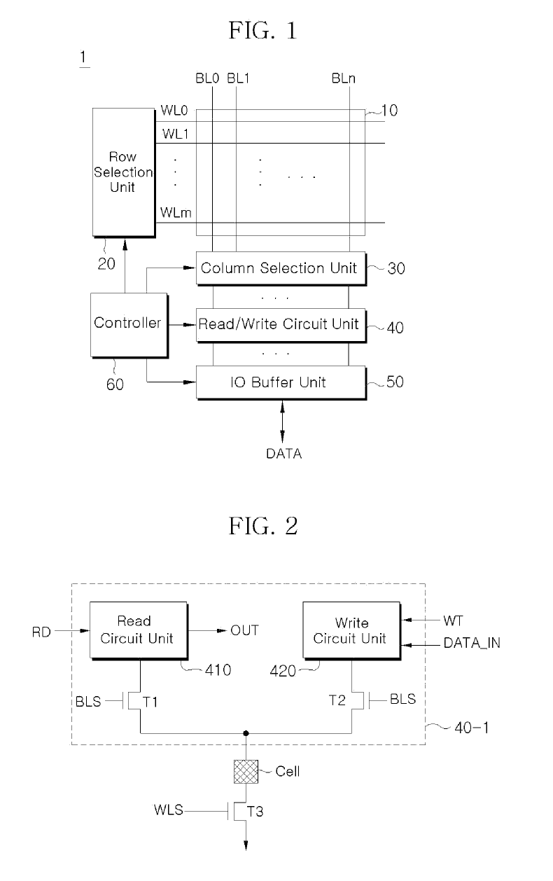

Referring to FIG. 1, a resistance variable memory apparatus 1 according to an embodiment may include a memory cell array 10, a row section unit 20, and a column selection unit 30. The resistance variable memory apparatus 1 may include a read/write circuit unit 40, an input/output (IO) buffer unit 50, and a controller 60.

The memory cell array 10 may include a plurality of memory cells coupled between a plurality of bit lines BL0 to BLn (where n is an integer greater than 0) and a plurality of word lines WL0 to WLm (where m is an integer greater than 0). Each of the memory cells may include a selecting element and a data storage unit, but is not limited thereto.

The row selection unit 20 may decode a row address signal provided from outside the resistance variable memory apparatus 1, and drive the decoded row address signal to the word lines WL0 to WLm. The column selection unit 30 may decode a column address signal provided from outside the resistance variable memory apparatus 1, and drive the bit lines BL0 to BLn according to an operation mode.

The read/write circuit unit 40 may read data from a selected memory cell of the memory cell array 10 and output the read data, during a read operation. Furthermore, the read/write circuit unit 40 may write data to a selected memory cell during a write operation.

The IO buffer unit 50 may receive data DATA from outside the resistance variable memory apparatus land provide the received data to the read/write circuit unit 40, during a write operation. Furthermore, the IO buffer unit 50 may receive data from the read/write circuit unit 40 and output the received data to the outside, during a read operation.

The controller 60 may be configured to control the overall operations of the resistance variable memory apparatus 1.

In an embodiment, the read/write circuit unit 40 may repeat a PNV cycle a designated number of times according to the control of the controller 60, during a write operation. While the PNV cycle is performed the designated number of times, the read/write circuit unit 40 may control verification operations that a reference value for the last verification operation has a different level from reference values for the other verification operations.

In an embodiment, the reference values for the verification operations excluding the last verification operation may have a higher level than the reference value for the last verification operation. Furthermore, the reference values for the verification operations excluding the last verification operation may have the same level or substantially the same level.

FIG. 2 is a configuration diagram of the representation of the read/write circuit unit according to an embodiment.

The read/write circuit unit 40-1 may include a read circuit unit 410 and a write circuit unit 420.

The read circuit unit 410 may generate a data output signal OUT. The data output signal OUT may be generated with the read circuit unit 410 by comparing cell data based on a current flowing in a selected memory cell to a reference value, in response to a read command RD. The read command RD may include a normal read command or verification read command.

The write circuit unit 420 may receive write data DATA_IN and program the received data to the memory cell, in response to a write command WT. The write data DATA_IN may be provided from the IO buffer unit 50 illustrated in FIG. 1.

The read/write circuit unit 40-1 may further include first to third switching elements T1 and T3. The first switching element T1 may be driven in response to a bit line select signal BLS. The first switching element T1 may electrically couple or separate the read circuit unit 410 from a memory cell. The second switching element T2 may be driven in response to the bit line select signal BLS. The second switching element T2 may electrically couple or separate the write circuit unit 420 from the memory cell Cell. The third switching element T3 may form a current path through the memory cell in response to a word line select signal WLS.

During a PNV operation, an operation of programming data to the memory cell through the write circuit unit 420 and an operation of verifying the cell data through the read circuit unit 410 may be repeated the designated number of times. Furthermore, the reference value for the last verification operation may be set to a different level from the reference values for the other verification operations.

FIG. 3 is a configuration diagram of the representation of the read circuit unit 100 according to an embodiment. The read circuit unit 100 may include a sense amplifier 110 and a reference value provider 120.

The sense amplifier 110 may generate a data output signal OUT. The data output signal OUT may be generated with the sense amplifier by comparing cell data, that is, a read current I_RD flowing in a memory cell to a reference value REF in response to the read command RD (see FIG. 2).

The reference value provider 120 may provide the reference value REF to the sense amplifier 110 in response to a reference value control signal PNV_LAST. The reference value REF may be determined as the PNV cycles are performed. In an embodiment, the reference value provider 120 may provide a first reference value having a first level as the reference value REF, during verification operations other than the last verification operation. Furthermore, the reference value provider 120 may provide a second reference value having a second level lower than the first level as the reference value REF, during the last verification operation.

Thus, before the last verification operation, the sense amplifier 110 may generate the data output signal OUT by comparing the first reference value to the read current I_RD. During the last verification operation, the sense amplifier 110 may generate the data output signal OUT by comparing the second reference value to the read current I_RD.

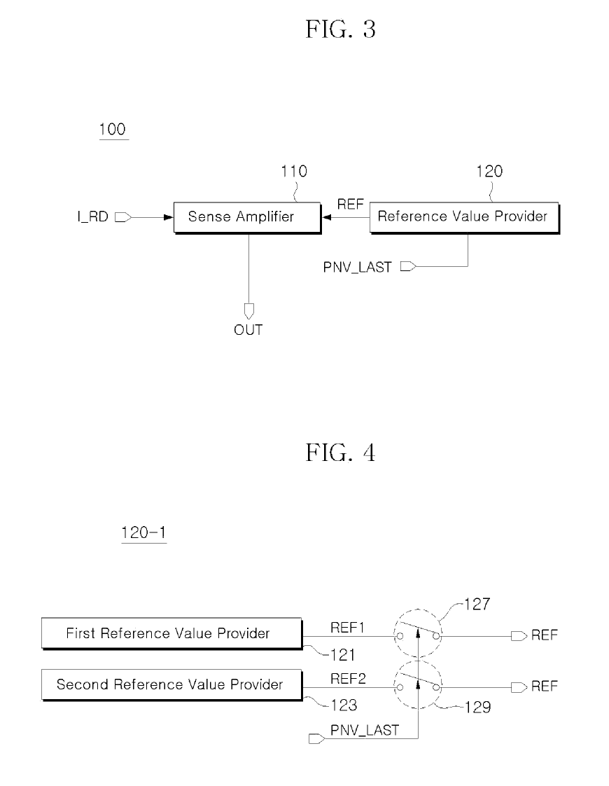

FIG. 4 is a configuration diagram of the representation of the reference value provider according to an embodiment.

The reference value provider 120-1 may include a first reference value provider 121 and a second reference value provider 123.

The first reference value provider 121 may generate the first reference value REF1 at the first level.

The second reference value provider 123 may generate the second reference value REF2 at the second level. The second level may be lower than the first level. In an embodiment, the second reference value REF2 may include a reference value for a normal read operation, but is not limited thereto. The second reference value REF2 may be set to a lower level than the first reference value REF1.

The reference value provider 120-1 may further include a first switch 127 coupled between an output terminal of the first reference value provider 121 and an output node of the reference value REF and a second switch 129 coupled between an output terminal of the second reference value provider 123 and the output node of the reference value REF. The first and second switches 127 and 129 may be controlled to be turned on/off according to the reference value control signal PNV_LAST.

The reference value control signal PNV_LAST may be generated in response to the number of the PNV cycles. During the verification operations excluding the last verification operation, the reference value control signal PNV_LAST may be generated to provide the first reference value REF1 as the reference value REF. Furthermore, during the last verification operation, the reference value control signal PNV_LAST may be generated to provide the second reference value REF2 as the reference value REF.

According to the level of the reference value control signal PNV_LAST, the first reference value REF1 or the second reference value REF2 may be provided as the reference REF to the sense amplifier 110, and then compared to the cell data I_RD.

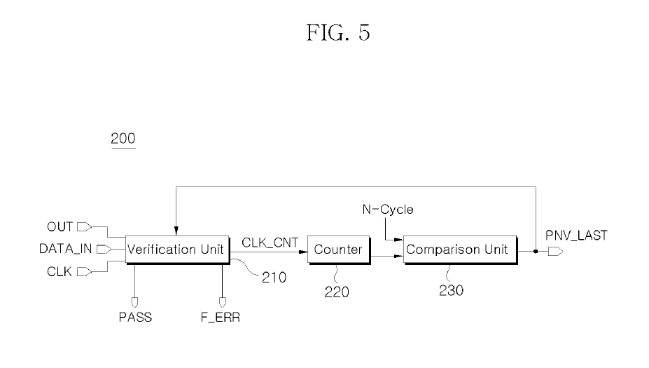

FIG. 5 is a configuration diagram of a representation of a control signal generator according to an embodiment.

The control signal generator 200 may be configured to generate the reference value control signal PNV_LAST. The reference value control signal PNV_LAST may be generated with the control signal generator 200 in response to a clock signal CLK, the input data DATA_IN, and the data output signal OUT received from the sense amplifier 110.

The control signal generator 200 may count the number of PNV cycles according to the level of the data output signal OUT, and generate the reference value control signal PNV_LAST at a level to turn on the first switch 127, before the PNV operation reaches the last cycle. When the PNV operation reaches the last cycle, the control signal generator 200 may generate the reference value control signal PNV_LAST at a level to turn on the second switch 129.

Referring to FIG. 5, the control signal generator 200 according to an embodiment may include a verification unit 210, a counter 220, and a comparison unit 230.

The verification unit 210 may output a verification pass signal PASS and a count control signal CLK_CNT according to whether the data output signal OUT is equal to the input data DATA_IN, in response to the clock signal CLK. For example, when a program operation was successfully completed during a PNV operation, the verification unit 210 may enable the verification pass signal PASS, and disable the count control signal CLK_CNT.

For example, when the PNV operation was not performed by the designated number of cycles and the program operation failed, the verification unit 210 may disable the verification pass signal PASS, and enable the count control signal CLK_CNT. Furthermore, when the PNV operation was performed by the designated number of cycles but the program operation failed, the verification unit 210 may enable an error flag signal F_ERR, and disable the count control signal CLK_CNT.

The counter 220 may perform a counting operation. The counting operation performed by the counter 220 may be performed in response to the count control signal CLK_CNT.

The comparison unit 230 may compare an output signal of the counter 220 to the designated PNV cycle number N-Cycle, and generate the reference value control signal PNV_LAST. When the PNV operation did not reach the designated number of cycles, the comparison unit 230 may generate the reference value control signal PNV_LAST at a level to turn on the first switch 127. When the PNV operation reached the designated number of cycles, the comparison unit 230 may generate the reference value control signal PNV_LAST at a level to turn on the second switch 129.

Thus, when the data output signal OUT is different from the input data DATA_IN while the PNV operation is performed, the reference value control signal PNV_LAST may be generated at a level to turn on the first switch 127, and the reference value provider 120 may output the first reference value REF1 as the reference value REF in response to the reference value control signal PNV_LAST. When the PNV operation reaches the last cycle, the reference value control signal PNV_LAST may be generated at a level to turn on the second switch 129, and the reference value provider 120 may output the second reference value REF2 as the reference value REF in response to the reference value control signal PNV_LAST.

When the data output signal OUT is equalized to the input data DATA_IN while the PNV operation is performed, the count control signal CLK_CNT generated by the verification unit 210 may be disabled to stop the generation of the reference value REF. Then, the PNV operation may be completed. However, when the PNV operation was performed by the designated number of cycles but the data output signal OUT is not equal to the input data DATA_IN, the error flag signal F_ERR may be enabled.

The control signal generator 200 may be included, for example, in the controller 60, but is not limited thereto. The controller signal generator 200 may be, for example, included in the read circuit unit 410 according to various modifications.

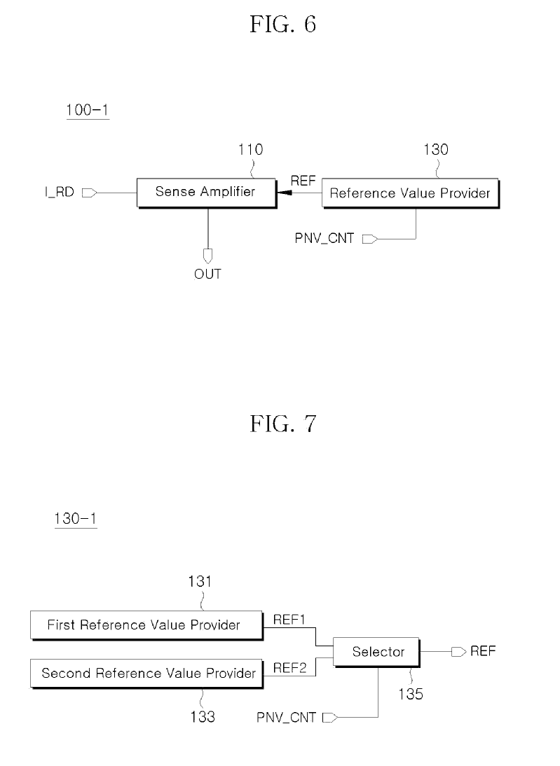

FIG. 6 is a configuration diagram of a representation of a read circuit unit according to an embodiment.

The read circuit unit 100-1 according to an embodiment may include a sense amplifier 110 and a reference value provider 130.

The sense amplifier 110 may generate a data output signal OUT by comparing cell data, that is, a read current I_RD flowing in a memory cell to a reference value REF in response to the read command RD (see FIG. 2).

The reference value provider 130 may provide the reference value REF to the sense amplifier 110. The reference value REF may be provided by the reference value provider 130 to the sense amplifier 110 in response to a verification count signal PNV_CNT. The reference value REF may be determined as the PNV cycles are performed.

In an embodiment, the reference value provider 130 (i.e. 130-1) may include a first reference value provider 131, a second reference value provider 133, and a selector 135, as illustrated in FIG. 7.

The first reference value provider 131 may generate a first reference value REF1 at a first level.

The second reference value provider 133 may generate a second reference value REF2 at a second level. The second level may be lower than the first level.

The selector 135 may select the first reference value as the reference value REF in response to the verification count signal PNV_CNT during verification operations other than the last verification operation. The selector 135 may select the second reference value as the reference value REF in response to the verification count signal PNV_CNT during the last verification operation.

Before the last verification operation, the sense amplifier 110 (See FIG. 6) may generate the data output signal OUT by comparing the first reference value to the read current I_RD. During the last verification operation, the sense amplifier 110 may generate the data output signal OUT by comparing the second reference value to the read current I_RD.

The verification count signal PNV_CNT may be generated by the controller 60 (i.e., see FIG. 1), for example, according to the preset PNV cycle number, but is not limited thereto.

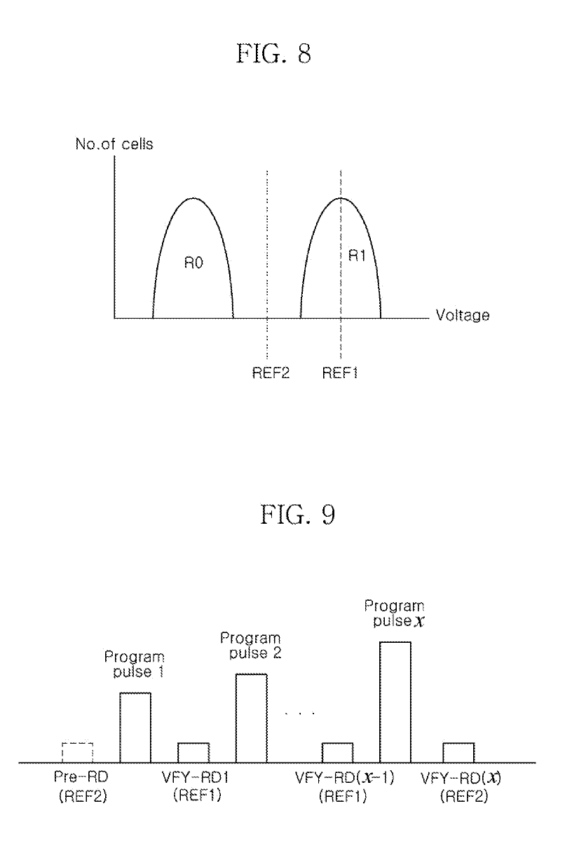

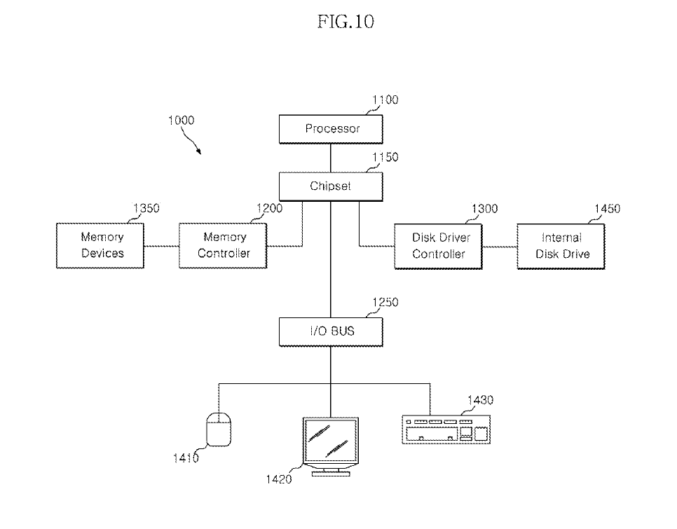

FIGS. 8 and 9 are conceptual views for explaining a representation of an operating method of the resistance variable memory apparatus according to an embodiment.

In the following descriptions, suppose that a resistance variable memory cell is programmed into a first resistance state RO or second resistance state R1.

As the number of uses or the time increases, the relative or absolute resistance state of the resistance variable memory apparatus may be adjusted by various changes in the internal elements thereof. Thus, in an embodiment, when the PNV operation is performed a designated number X of times as illustrated in FIGS. 8 and 9, the first reference value REF1 may be used as the reference value REF during verification operations VFY-RD1 to VFY-RD(x−1) excluding the last verification operation. During the last verification operation VFY-RD(x), the second reference value REF2 may be used as the reference value REF.

In FIG. 9, a pre-read operation Pre-RD may indicate an operation of previously reading data of a selected memory cell, before a program operation is performed.

The first reference value REF1 may be set to a higher level than a reference value through which the resistance state of a memory cell is determined. Thus, the last verification operation may be performed using the reference value REF2 which may be substantially equal to the reference value during a normal read operation. In these examples, memory cells which are determined as pass based on the second reference value REF2 may be considered to be successfully programmed.

The resistance variable memory apparatus and/or read/write circuit unit and/or operating method discussed above (see FIGS. 1-9) are particular useful in the design of memory devices, processors, and computer systems. For example, referring to FIG. 10, a block diagram of a system employing the resistance variable memory apparatus and/or read/write circuit unit and/or operating method in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one resistance variable memory apparatus and/or read/write circuit unit and/or operating method as discussed above with reference to FIGS. 1-9. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one resistance variable memory apparatus and/or read/write circuit unit and/or operating method as discussed above with relation to FIGS. 1-9, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 10 is merely one example of a system employing the resistance variable memory apparatus and/or read/write circuit unit and/or operating method as discussed above with relation to FIGS. 1-9. In alternate embodiments, such as cellular phones or digital cameras, the components may differ from the embodiments illustrated in FIG. 10.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A resistance variable memory apparatus comprising:
a memory cell array; and
a read/write circuit unit configured for being controlled so that a reference value for a last verification operation has a different level from reference values for verification operations excluding the last verification operation, while a preset number of program and verification (PNV) cycles are performed in response to a write command for the memory cell array.

2. The resistance variable memory apparatus according to claim 1, wherein the read/write circuit unit comprises a reference value provider configured to determine a first or second reference value as the reference value, in response to a reference value control signal.

3. The resistance variable memory apparatus according to claim 2, wherein the read/write circuit unit comprises a sense amplifier configured to compare a read current in a memory cell to the reference value, and generate a data output signal.

4. The resistance variable memory apparatus according to claim 2, wherein the reference value provider comprises:
a first reference value provider configured to output the first reference value;
a first switch configured to provide the first reference value as the reference value in response to the reference value control signal;
a second reference value provider configured to output the second reference value; and
a second switch configured to provide the second reference value as the reference value in response to the reference value control signal.

5. The resistance variable memory apparatus according to claim 2, wherein the second reference value is set to a lower level than the first reference value.

6. The resistance variable memory apparatus according to claim 2, wherein the second reference value has substantially the same level as a reference value for a normal read operation, and the first reference value is set to a lower level than the second reference value.

7. The resistance variable memory apparatus according to claim 2, further comprising a control signal generator configured to count the number of PNV cycles according to the level of cell data read from a selected memory cell in response to a verification read command, and generate the reference value control signal for selecting the first reference value as the reference value before the last verification operation, and selecting the second reference value as the reference value during the last verification operation.

8. The resistance variable memory apparatus according to claim 7, wherein the control signal generator comprises:
a verification unit configured to output a count control signal according to whether the cell data is equal to input data, in response to a clock signal;
a counter configured to perform counting in response to the count control signal; and
a comparison unit configured to compare an output signal of the counter to the preset PNV cycle number and generate the reference value control signal.

9. The resistance variable memory apparatus according to claim 8, wherein the verification unit is configured to enable a verification pass signal and disable the count control signal, when the cell data is equal to the input data while the preset number of PNV cycles are performed.

10. The resistance variable memory apparatus according to claim 8, wherein the verification unit is configured to disable a verification pass signal and enable the count control signal, when the cell data is not equal to the input data while the preset number of PNV cycles are performed.

11. The resistance variable memory apparatus according to claim 8, wherein the verification unit is configured to enable an error flag signal and disable the count control signal, when the cell data is not equal to the input data after the preset number of PNV cycles are completed.

12. The resistance variable memory apparatus according to claim 1, wherein the read/write circuit unit comprises a reference value provider configured to output the reference value, and
the reference value provider comprises:
a first reference value provider configured to output a first reference value;
a second reference value provider configured to output a second reference value; and
a selector configured to select the first or second reference value as the reference value in response to a verification count signal generated on the basis of how many times the PNV cycle has been performed.

13. A read/write circuit unit comprising:
a write circuit unit configured to program input data to a selected memory cell in response to a write command; and
a read circuit unit configured for being controlled so that a reference value for a last verification operation has a different level from reference values for verification operations excluding the last verification operation, while a preset number of program and verification (PNV) cycles are performed in response to the write command.

14. The read/write circuit unit according to claim 13, wherein the read circuit unit comprises a reference value provider configured to determine a first or second reference value as the reference value, in response to a verification count signal.

15. The resistance variable memory apparatus according to claim 14, wherein the read/write circuit unit comprises a sense amplifier configured to compare a read current with the reference value, and generate a data output signal.

16. The read/write circuit unit according to claim 13, wherein the read circuit unit comprises a reference value provider configured to determine a first or second reference value as the reference value, in response to a reference value control signal.

17. The read/write circuit unit according to claim 16, wherein the reference value provider comprises:
a first reference value provider configured to output the first reference value;
a first switch configured to provide the first reference value as the reference value in response to the reference value control signal;
a second reference value provider configured to output the second reference value; and
a second switch configured to provide the second reference value as the reference value in response to the reference value control signal.

18. The resistance variable memory apparatus according to claim 16, wherein the second reference value is set to a lower level than the first reference value.

19. The read/write circuit unit according to claim 16, wherein the second reference value has substantially the same level as a reference value for a normal read operation, and the first reference value is set to a lower level than the second reference value.

20. The read/write circuit unit according to claim 13, further comprising a reference value provider configured to output the reference value, and
the reference value provider comprises:
a first reference value provider configured to output a first reference value;
a second reference value provider configured to output a second reference value; and
a selector configured to select the first or second reference value as the reference value in response to a verification count signal generated on the basis of how many times the PNV cycle has been performed.

21. The read/write circuit unit according to claim 20, wherein the second reference value has substantially the same level as a reference value for a normal read operation, and the first reference value is set to a lower level than the second reference value.

22. An operating method of a resistance variable memory apparatus including a read/write circuit unit,
controlling the read/write circuit unit so that a reference value for the last verification operation has a different level from reference values for verification operations excluding the last verification operation, while a preset number of program and verification (PNV) cycles are performed in response to a write command.

23. The operating method according to claim 22, wherein the reference values for the verification operations excluding the last verification operation have a higher level than the reference value for the last verification operation.

24. The operating method according to claim 23, wherein the reference value for the last verification operation has substantially the same level as a reference value for a normal read operation.
